(19) United States
(12) Patent Application Publication
(10) Pub. No.: US 2014/0179107 A1
(43) Pub. Date: Jun. 26, 2014

(54) Etching Silicon Nitride Using Dilute Hydrofluoric Acid

(71) Applicant: INTERMOLECULAR INC., San Jose, CA (US)

(72) Inventor: Gregory Nowling, San Jose, CA (US)

(73) Assignee: INTERMOLECULAR INC., San Jose, CA (US)

(21) Appl. No.: 13/723,613

(22) Filed: Dec. 21, 2012

(51) Int. Cl. H01L 21/306

(52) U.S. Cl. CPC H01L 21/30604
USPC 438/694; 438/757

(57) ABSTRACT

Provided are methods for processing semiconductor substrates or, more specifically, methods for etching silicon nitride structures without damaging photoresist structures that are exposed to the same etching solutions. In some embodiments, a highly diluted hydrofluoric acid is used for etching silicon nitride. A volumetric ratio of water to hydrofluoric acid may be between 1000:1 and 10,000:1. This level of dilution results in a low etching selectivity of photoresist to silicon nitride. In some embodiments, this selectivity is less than 0.2 and even less than 0.02. The solution may be kept at a temperature of between 60° C. and 90° C. to increase silicon nitride etching rates and to maintain high selectivity. The process may proceed until complete removal of the silicon nitride structure, while the photoresist structure may remain substantially intact.

### BACKGROUND

Semiconductor devices have dramatically decreased in size in the last few decades. Many modern devices include features that are less than 100 nanometers in size, e.g., 45 nanometers and/or 32 nanometers. As device and feature sizes continue to shrink, processing methods need to be improved.

Silicon nitride films have been widely adopted by the semiconductor industry. For example, silicon nitride may be formed as temporary spacers in metal oxide semiconductor (MOS) devices, such as metal oxide semiconductor field effect transistors (MOSFETs). Specifically, silicon nitride spacers may be used during fabrication of lightly doped drain (LDD) regions to facilitate different levels of doping for the drain/source regions as well as for the LDD regions. The LDD region can be controlled by the lateral spacer dimension. Furthermore, silicon nitride caps may be initially deposited over gate oxides and later removed. Silicon nitride is also used in various other semiconductor applications.

Silicon nitride is conventionally removed using a boiling or near boiling phosphoric acid solution. The concentration of phosphoric acid in the solution is kept high (e.g., above 85%) in order to achieve higher operating temperatures (e.g., 160° C. and above) and faster etching rates. Other approaches to remove silicon nitride structure involve dry etch. However, these processes often lead to erosion of other structures provided on the substrate, such as photoresist and silicon oxide.

### SUMMARY

Provided are methods for processing semiconductor substrates or, more specifically, methods for etching silicon nitride structures without damaging photoresist structures, silicon oxide structures, and/or other structures exposed to etching solutions used to remove silicon nitride. The substrates may include non-volatile memory circuitry, such as flash memory circuitry, protected by photoresist layers from damage during processing of other substrate portions. For example, the same substrate may include non-volatile memory circuitry and logic circuitry. The non-volatile memory circuitry may be covered by a photoresist layer, while the logic circuitry may include a silicon nitride structure, which needs to be removed without damaging the photoresist layer. If the photoresist layer experience significant damage during etching, it may be become permeable to an etching solution, which may penetrate the photoresist layer and damage structures provided under the photoresist layer.

In some embodiments, a highly diluted hydrofluoric acid in water is used for etching silicon nitride. A volumetric ratio of water to hydrofluoric acid may be between 1000:1 and 10,000:1. This level of dilution results in a high etching selectivity of silicon nitride to photoresist and, in some embodiments, in a high etching selectivity of silicon oxide to photoresist or, in other words, a low selectivity of photoresist to silicon nitride and a low selectivity of photoresist to silicon oxide. In some embodiments, the photoresist-to-silicon nitride selectivity is less than 0.2 and even less than 0.02. The solution may be kept at a temperature of between 60° C. and 90° C. to increase silicon nitride etching rates and to maintain high selectivity. The process may proceed until complete removal of the silicon nitride structure, while the photoresist structure may remain substantially intact.

In some embodiments, a method for processing semiconductor substrates involves providing a semiconductor substrate that includes a first structure and a second structure. The first structure may include a photoresist, while the second structure may include silicon nitride. The method may proceed with exposing the semiconductor substrate to an etching solution that includes hydrofluoric acid and water. In some embodiments, a volumetric ratio of water to hydrofluoric acid in the etching solution is between about 1000:1 and about 10,000:1, for example, about 5,000:1. The method proceeds with etching the second structure, while the semiconductor substrate is being exposed to the etching solution. The first structure may remain substantially intact after this etching operation. The etching selectivity of the first structure relative to the second structure may be less than about 0.2. In some embodiments, this selectivity is less than about 0.02 an even less than about 0.005. In some embodiments, the etching rate of the second structure is at between about 3 Angstroms per minute and 200 Angstroms per minute or, more specifically, between about 30 Angstroms per minute and 200 Angstroms per minute. The etching rate of the second structure may be less than about 100 Angstroms per minute. The silicon nitride structure may be relatively thin and even these etching rates may be sufficiently to remove this structure within a reasonable timeframe. The second structure may be between 20 Angstroms and 1000 Angstroms thick prior to etching or, more specifically, between about 30 Angstroms and 100 Angstroms. In some embodiments, a thickness of the first structure is reduced by less than 200 Angstroms while etching the second structure. In some embodiments, the second structure is completely removed from the semiconductor substrate.

In some embodiments, the etching solution is held at a temperature of between 50° C. and 100° C. while etching the second structure or, more specifically, between 60° C. and 90° C. or, even more specifically, between 75° C. and 85° C. Dilution and increased temperature tend to increase the silicon nitride-to-photoresist selectivity (or reduce the photoresist-to-silicon nitride selectivity).

In some embodiments, the second structure is provided over a third structure that includes silicon oxide. The third structure may remain substantially intact when exposed to the etching solution after removal of the second structure. The etching selectivity of the third structure relative to the second structure may be less than about 0.05 or, more specifically, less than about 0.01. The third structure may be between 20 Angstroms and 1000 Angstroms thick prior to etching or, more specifically, between about 30 Angstroms and 100 Angstroms. In some embodiments, a thickness of the third structure is reduced by less than 5 Angstroms while etching the second structure.

In some embodiments, the second structure may be formed by depositing silicon nitride using plasma enhanced chemical vapor deposition (PECVD) or by low pressure chemical vapor deposition (LPCVD). In some embodiments, the second structure is disposed over a logic portion of the semiconductor substrate. The first structure may be disposed over a memory portion of the semiconductor substrate.

A method for processing semiconductor substrates may involve providing a semiconductor substrate including a first structure, a second structure, and a third structure. The first structure may include a photoresist, while the second structure may include silicon nitride. The thickness of the second structure may be between 20 Angstroms and 1000 Angstroms. The third structure may include silicon oxide and being covered by the second structure. The method may proceed with exposing the semiconductor substrate to an etching solution including hydrofluoric acid and water at a volumetric ratio of water to hydrofluoric acid of 1000:1 and 10,000:1. The etching solution is kept at a temperature of between 60° C. and 90° C. while etching away the second structure. During removal of the second structure, the thickness of the first structure is reduced by less than 20 nanometers, while the third structure remains substantially intact. The etching selectivity of the first structure relative to the second structure may be less than about 20 and even less than about 100. In some embodiments, the second structure is disposed over a logic portion of the semiconductor substrate, while the first structure is disposed over a memory portion of the semiconductor substrate.

These and other embodiments are described further below with reference to the figures.

### BRIEF DESCRIPTION OF THE DRAWINGS

FIGS. 1A and 1B illustrate schematic representations of semiconductor substrate portions before and after removal of a silicon nitride structure, in accordance with some embodiments.

FIG. 1C illustrates a schematic representation of another semiconductor substrate processed using etching methods described herein, in accordance with some embodiments.

FIG. 2 illustrates a process flowchart corresponding to a method of processing a semiconductor substrate to remove silicon nitride structures while retaining photoresist and/or other structures substantially intact, in accordance with some embodiments.

FIG. 3 illustrates a schematic representation of an etching apparatus for processing a semiconductor substrate to remove silicon nitride structures from the surface of the substrate, in accordance with some embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

Silicon nitride structures have many important applications in semiconductor devices, such as spacers in metal-oxide semiconductor (MOS) transistor devices, header caps over gate dielectrics, oxygen diffusion barriers, mechanical protection layers, and electrical insulators with relative high dielectric constants. Often silicon nitride structures are used temporarily and need to be removed from the substrate. This removal should be performed without damaging other structures, such as photoresist and silicon oxides.

Provided are methods for processing semiconductor substrates including silicon nitride and photoresist structures. For example, a silicon nitride structure may be provided in one area of a substrate (e.g., a logic area), while a photoresist structure may be provided in another area (e.g., memory area). The substrate may also include other structures that may get exposed to an etching solution. Furthermore, removal of the silicon nitride structure may expose another structure underneath the silicon nitride structure to the etching solution, such as a silicon oxide structure.

In some embodiments, a silicon nitride structure may be removed from a substrate without damaging a photoresist structure and possibly other structures that are exposed to the same etching solution. As such, etching is performed using solutions and/or conditions that provide high etching selectivity of silicon nitride to other materials, such as to the photoresist and/or to silicon oxide. For purposes of this disclosure, an etching selectivity is defined as a ratio of two etching rates, e.g., a ratio of a silicon nitride etching rate to a photoresist etching rate. In some embodiments, the photoresist-to-silicon nitride selectivity is less than 0.2 and even less than 0.02. In general, the lower selectivity values (of the photoresist-to-silicon nitride) are desirable to prevent damage to the photoresist and/or other structures.

The selectivity may be achieved by using highly diluted hydrofluoric acid in water. In some embodiments, a volumetric ratio of water to hydrofluoric acid may be between about 1000:1 and 10,000:1, e.g., about 5000:1. This level of dilution is quite different from conventionally used hydrofluoric acid solutions, in which this ratio is typically between 10:1 and 100:1. The conventionally used hydrofluoric acid solutions are simply not capable to achieve selectivity values listed above. For example, a 5000:1 solution (i.e., 5000 parts by volume of water per one part by volume of hydrofluoric acid) kept at 80° C. is capable of achieving the silicon nitride-to-photoresist selectivity of 70 (or the photoresist-to-silicon nitride selectivity of 0.014), while a 1000:1 solution kept at the same temperature is capable of achieving the silicon nitride-to-photoresist selectivity of only 6 (or the photoresist-to-silicon nitride selectivity of 0.017). Further increasing concentration of hydrofluoric acid in water results in even less selective etching. In fact, concentrated hydrofluoric acid solutions are frequently used to strip photoresist and are not suitable for applications when photoresist integrity needs to be preserved. Furthermore, many other conventional processes used to remove silicon nitride structures, such as high temperature (150-160° C.) phosphoric acid solutions, are damaging to photoresist.

The temperature of the etching solution also impacts selectivity. It was found that increasing the temperature of the etching solution tends to increase the silicon nitride-to-photoresist selectivity (or to reduce the photoresist-to-silicon nitride selectivity). However, operating near the boiling point of the solution, which may be about 100° C., may cause concentration fluctuations and changes in selectivity due to the solution becoming less diluted. In some embodiments, the solution is kept at a temperature of between 50° C. and 100° C. or, more specifically, between 60° C. and 90° C. or, even more specifically, between 75° C. and 85° C. Furthermore, higher temperatures correspond to higher silicon nitride etch rates. In some embodiments, the method may proceed until complete removal of the silicon nitride structure, while the photoresist structure may remain substantially intact.

It was also found that etching rates depend on stoichiometry, morphology, and other characteristics of silicon nitride materials, processing conditions (e.g., substrate temperatures) used during deposition of these materials, and physical characteristics (e.g., density) of resulting structures. For example, silicon nitride structures formed using plasma enhanced chemical vapor deposition (PECVD) exhibit etching rates that are three times greater than structures formed using low pressure chemical vapor deposition (LPCVD). LPCVD of silicon nitride may be performed at temperatures 600-800° C. using a silicon containing precursor (e.g., silane, bis(tertiary-butylamino)silane, dichlorosilane) and a nitrogen containing precursor (e.g., nitrogen, ammonia) in a deposition chamber maintained at 0.1-10 Torr.

In some embodiments, silicon nitride structures may be formed using nitridation of silicon by exposing a silicon surface to nitrogen (e.g., at 1300° C.), to ammonia (e.g., at 1100-1300° C.), or to hydrazine (e.g., at 1100-1300° C.). Ammonia may be also used to convert silicon dioxide into silicon nitride. Silicon nitride structures be also deposited using various chemical vapor deposition (CVD) techniques, such as CVD using silicon chloride, silicon bromides, silicon fluoride, and silane as precursors and combining these gases with ammonia or hydrazine (e.g., at 500-1100° C.). UV sensitized, platinum catalyzed, low pressure, and RF and DC “glow” variations of CVD may be used as well. Furthermore, silicon nitride structures may be deposited using reactive or direct RF sputtering, electron beam evaporation, and ion implantation.

A photoresist may be coated over a substrate to facilitate masking of certain portions of the substrate. A spin coating process may be used for this purpose. The average thickness of a photoresist may be less than about 10,000 Angstroms, e.g., between about 2,000 Angstroms and 6,000 Angstroms. The photoresist may include an organic material, such as a radiation sensitive organic material. Some examples include diazonaphthoquinone (DNQ), novolac resin, or other suitable positive resist type material. Specific examples include Hoechst AZ 4620 and Hoechst AZ 4562 supplied by Hoechst/AZ Electronic Materials and Shipley 1400-17, Shipley 1400-27, Shipley 1400-37, and Shipley microposit developer supplied by Shipley/Rohm and Haas. The exposure for the initially coated photoresist may proceed with decomposition of diazoquinone that corresponds to evolution of nitrogen gas and production of carbenes in the exposed layer.

The silicon oxide structures may be prepared using thermal oxidation of a silicon surface of a substrate. For example, oxygen may be supplied over a silicon substrate heated to about 800° C.-1200° C. at atmospheric pressure.

### Semiconductor Device Examples

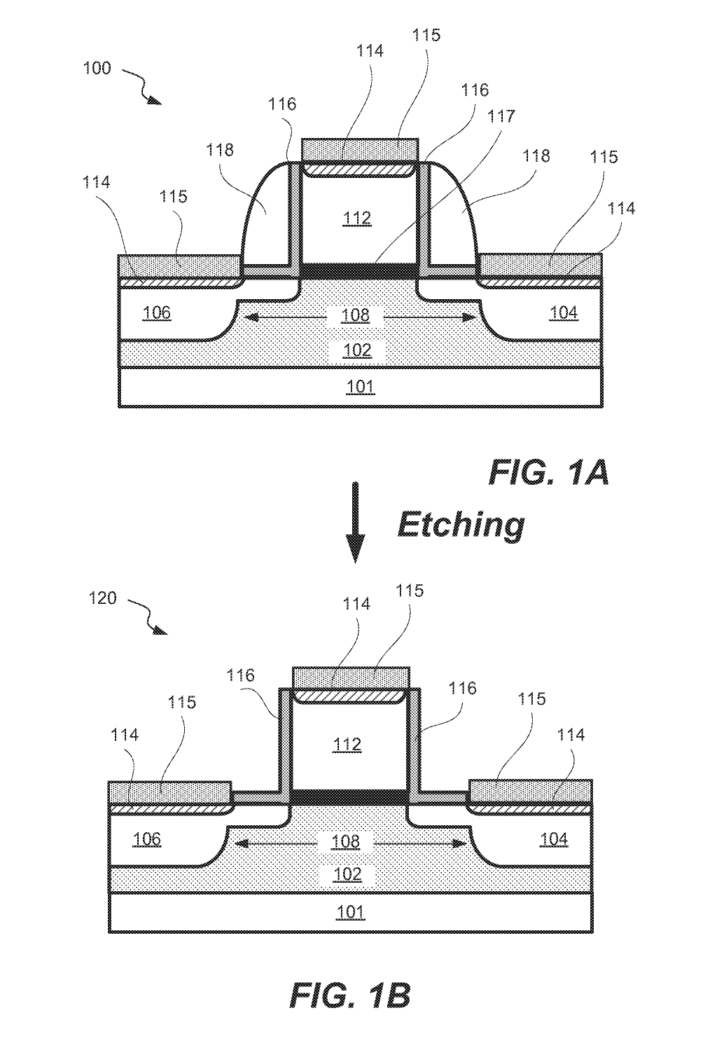

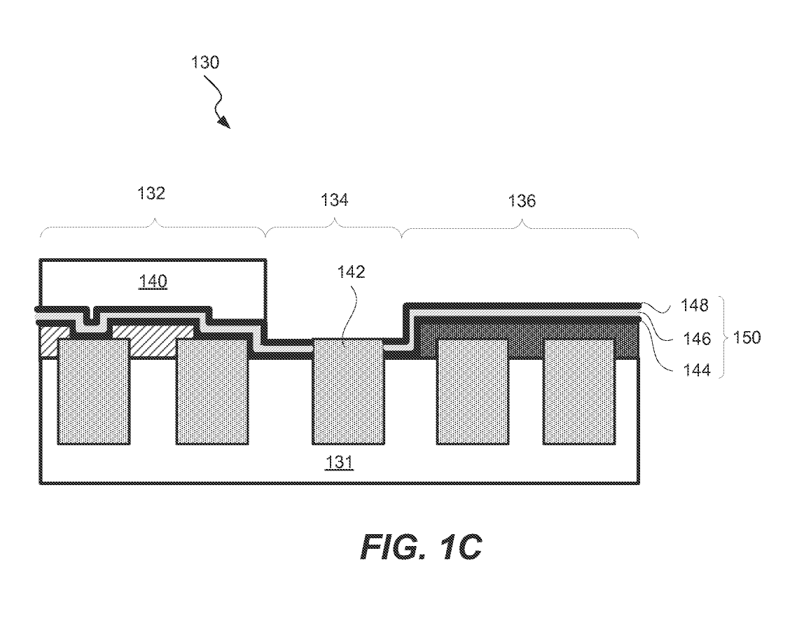

Prior to describing further details of etching, a brief description of semiconductor device examples is presented below to provide better understanding of various processing features. Specifically, FIGS. 1A and 1B illustrate schematic representations of substrate portions including MOS device 100 before etching and the same device 120 after etching, in accordance with some embodiments. The references below are made to p-type metal-oxide-semiconductor (PMOS) devices but other types of devices can be used and will be understood by one having ordinary skill in the art. PMOS device 100 may include a p-doped substrate 101 and an n-doped well 102 within substrate 101. Substrate 101 is typically a part of an overall wafer substrate together with other transistors and devices. P-doped substrate 101 may include any suitable p-type dopants, such as boron and indium, and may be formed by any suitable technique. N-doped well 102 may include any suitable n-type dopants, such as phosphorus and arsenic, and may be formed by any suitable technique. N-doped well 102 may be formed by doping substrate 101 by ion implantation, for example.

Device 100 also includes a conductive gate electrode 112 that is separated from n-doped well 102 by gate dielectric 117. Gate 112 may include any suitable material. In some embodiments, gate 112 may comprise polysilicon. In some embodiments, gate 112 may include polysilicon doped with a p-type dopant, such as boron. Typically, gate dielectric 117 is deposited in the form of silicone dioxide, but other gate dielectric materials can be also selected, such as hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide aluminum oxide, lead scandium tantalum oxide, or lead zinc niobate.

Device 100 also includes p-doped source region 104 and drain region 106 (or simply the source and drain) in n-doped well 102. Source 104 and drain 106 are located on each side of gate 112 forming channel 108 within well 102. Source 104 and drain 106 may include a p-type dopant, such as boron. Additionally, source 104 and drain 106 may be formed in recesses of n-doped well 102.

Device 100 is also shown having sidewall spacers 118 along the sidewalls of gate 112. Spacers 118 may include any suitable dielectric materials, such as silicon nitride. In some embodiments, spacers 118 are between about 200 Angstroms and 400 Angstroms in size, e.g., about 300 Angstroms. It should be noted that spacers 118 may be removed during etching and, therefore, are not shown in FIG. 1B.

In some embodiments, source 104 and drain 106 and gate 112 are covered with a layer of self-aligned silicide portions 114, which may be referred to as salicide portions or simply salicides. For example, a layer of cobalt is deposited as a blanket and thermally treated to form these portions 114. Alternatively, nickel or other refractory metals, such as tungsten, titanium, and palladium, and are suitable for forming silicide portions 114.

A sequence of forming some of these components will now be described. Usually, sidewall spacers 118 are formed after forming gate 112. Liner 116 made from, for example, silicon dioxide may be interposed between spacers 118 and gate 112. Liner 116 may be L shaped and have a thickness of about 30-120 Angstroms. Liner 116 may further include an offset spacer (not shown).

Source 104 and drain 106 are formed after formation of sidewall spacers 118 using, for example, ion implantation. After the source and drain formation, the overall substrate may be subjected to an annealing and/or activation thermal process. The process may continue with forming silicide portion 114 by self-aligned silicide (salicide) technique. The blanket metal film may be subjected to rapid thermal process (RTP) to react the metal layer with the silicon contained within the gate structure and the source/drain region to form a metal silicide. The temperature for RTP may be in the range of 700° C. to 1000° C.

Spacers 118 are then etched, leaving liner 116 exposed as shown in FIG. 1B. Photoresist 115 may be provided on silicide portions 114 or other parts of the substrate to protect these parts during etching. However, photoresist 115 should not be removed or otherwise deteriorated during etching such that these parts are exposed or, more generally, protection provided by photoresist 115 is compromised.

In some embodiments, a semiconductor substrate includes a silicon nitride cap, which is removed from the substrate using methods described herein. For example, the silicon nitride cap may be provided over the gate dielectric in a structure similar to the one described above with reference to FIGS. 1A-1B. The thickness of the silicon nitride cap may be between about 300 Angstroms and 1000 Angstroms or, more specifically, between about 400 Angstroms and 600 Angstroms. Sidewalls of the gate dielectric may be protected by silicon oxide spacers, which, in some embodiments, may be provided over silicon nitride structures. The selectivity of silicon oxide to silicon nitride may be at less than about 0.025 or even at least about 0.017. This level of selectivity preserves the silicon oxide side walls during removal of the silicon nitride cap. In some embodiments, this structure does not have photoresist present.

FIG. 1C illustrates another example of device 130 that may be processed in accordance with the methods described herein. Specifically, device 130 may include a memory portion 132, a high voltage portion 134, and a logic portion 136. Other portions or fewer portions may be provided on device 130. Substrate 131 may be used to support these different portions. As such, when logic portion 136 is processed, memory portion 132 and high voltage portion 134 are exposed to the processing environments used for processing logic portion 136. To avoid damaging portions that are not being processed, these portions (i.e., logic portion 136 in FIG. 1C) may be masked with a photoresist layer.

In some embodiments, logic portion 136 is covered by a stack 150 of three layers 144, 146, 148. Bottom layer 144 and top layer 148 may be made from silicon oxide, while middle layer 146 may be made from silicon nitride. Bottom layer 144 may be between about 300 Angstroms and 700 Angstroms thick, such as about 500 Angstroms thick. Middle layer 146 may be between about 300 Angstroms and 700 Angstroms thick, such as about 500 Angstroms thick. Top layer 148 may be between about 400 Angstroms and 800 Angstroms thick, such as about 600 Angstroms thick. In some embodiments, stack 150 also extends into high voltage portion 134.

Top silicon oxide layer 148 and middle silicon nitride layer 146 of stack 150 may be removed leaving bottom silicon oxide layer 144 to protect the underlying silicon structures. Memory portion 132 should not be impacted during removal of top layer 148 and middle layer 146. Specifically, memory portion 132 may be protected by photoresist layer 140. One area of concern is lateral erosion of photoresist layer 140. Lateral photoresist erosion may expose the structures in memory portion 132. As a result of this exposure, the structures and corresponding devices can be damaged while removing nitrides or subsequent processing (e.g., removing oxide layer 144 of stack 150) and/or processed used to build devices in high-voltage region 134. As such, photoresist layer 140 should be substantially intact during removal of layer 148 and middle layer 146.

Top silicon oxide layer 148 may be removed using various conventional techniques. For example, conventional hydrogen fluoride and buffered oxide etch (BOE) solutions may be used to remove layer 148 at temperatures of 25-50° C. without damaging photoresist 140.

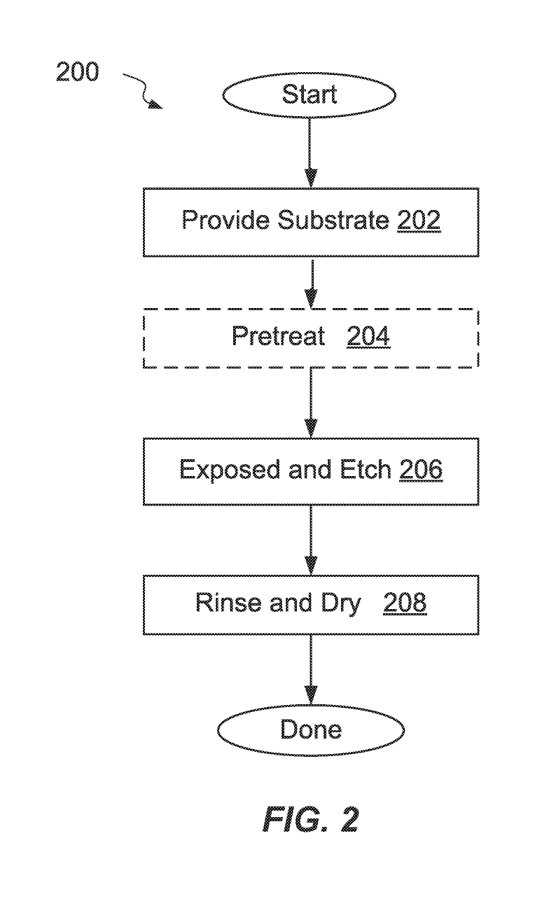

The silicon nitride layer of stack 150 (e.g., middle layer 146) may be removed in accordance with techniques described below with reference to FIG. 2. It should be noted that because a highly diluted hydrofluoric acid is used, removal of middle layer 146 will not impact underlying bottom layer 144 made from silicon oxide.

### Processing Examples

FIG. 2 illustrates a process flowchart corresponding to method 200 of processing a semiconductor substrate to remove silicon nitride containing structures from the surface of the substrate containing photoresist and/or other structures, in accordance with some embodiments. Method 200 may commence with operation 202, during which a semiconductor substrate including one or more silicon nitride structures and photoresist structures is provided. Some substrate examples are described above with reference to FIGS. 1A-1C. In some embodiments, the silicon nitride structure may be disposed over a silicon oxide structure. The silicon nitride structure may be between 200 Angstroms and 1000 Angstroms thick prior to etching. The photoresist structure may be between 2,000 Angstroms and 10,000 Angstroms thick prior to etching.

Method 200 may proceed with an optional pretreatment operation 204. This operation may involve exposing the semiconductor substrate or at least its silicon nitride structure to a pretreatment solution to remove native oxides form surfaces of these structures. In some embodiments, the pretreatment solution includes hydrofluoric acid at a concentration of less than 5 weight percent. The pretreatment solution may be maintained at a room temperature. The exposure to the pretreatment solution may last between about 10 seconds and 5 minutes, for example, about 1 minute. Excessive hydrofluoric acid concentrations, duration, and temperature should be avoided to prevent damage to other components of the device, such as a liner made from silicon oxide. After completing operation 204, the substrate may be rinsed to remove residual cleaning solution. Operation 206 may be started relatively soon to prevent formation of a new native oxide after completion of operations 204. It should be noted that silicon oxide structures (other than native silicon oxides formed over silicon and silicon nitride structures) may not be exposed during pretreatment operation 204.

Method 200 may proceed with exposing the semiconductor substrate to an etching solution and etching the silicon nitride structure during operation 206. The etching solution includes a highly diluted hydrofluoric acid in water. In some embodiments, a volumetric ratio of water to hydrofluoric acid in the etching solution is between 1000:1 and 10,000:1, such as 5000:1.

In some embodiments, the etching solution may include one or more polar solvents, such as ethylene glycol (EG), propylene carbonate (PC), dichloromethane (DCM), tetrahydrofuran (THF), ethyl acetate, acetone, dimethylformamide (DMF), acetonitrile (MeCN), dimethyl sulfoxide (DMSO), propylene carbonate, formic acid, n-butanol, isopropanol (IPA), n-propanol, ethanol, methanol, and acetic acid. These polar solvents may be used in addition to or instead of water. When multiple solvents are used, the dilution of hydrofluoric acid is specified for a combined volume of all solvents. In some embodiments, the etching solution includes a non-fluorinated acid, such as hydrochloric acid, sulfuric acid, and nitric acid. These acids may be used to adjust the acidity of the etching solution. In some embodiments, the etching solution has a pH of between about −1 to 3.

In some embodiments, the etching solution includes a silicon-containing additive. Some examples of such additives include silica and seasoning the dilute-HF batch by first etching dummy wafers coated with blanket silicon nitride prior to etching the actual device wafers. The concentration of silicon-containing additives may be less than about 1 weight percent or, more specifically, less than about 0.5 weight percent.

In some embodiments, the etching solution is maintained at a temperature of between about 50° C. and 100° C. while etching the second structure or, more specifically, between 60° C. and 90° C. or even between 75° C. and 85° C. As stated above, the etching rate increases with the temperature. The silicon nitride-to-photoresist selectivity increases (or the photoresist-to-silicon decreases) with the temperature. However, higher temperatures may cause evaporation and boiling of the etching solution and may cause changes in concentration if not properly controlled.

The silicon nitride structure is removed from the substrate by maintaining the substrate in the etching solution for a predetermined period of time. This time is usually driven by the size of the silicon nitride structure and etching rate. In some embodiments, the etching rate of the silicon nitride structure is between about 3 Angstroms per minute and 200 Angstroms per minute or, more specifically, between about 30 Angstroms per minute and 200 Angstroms per minute. In some embodiments, the etching rate of the silicon nitride structure is less than 100 Angstroms per minute.

Etching operation 206 may result in complete or near complete removal of the silicon nitride structures. However, other structures provided on the same substrate and exposed to the etching solution may remain substantially intact. The relative impacts of the etching solution on different structures may be expressed with a ratio of etching rate, i.e., an etching selectivity. In some embodiments, the photoresist-to-silicon nitride selectivity is less than about 0.2 or, more specifically, less than about 0.02, even less than about 0.005. In some embodiments, the thickness of the photoresist structure is reduced by less than 200 Angstroms while etching the silicon nitride structure.

After completion of operation 206, method 200 may proceed with rinsing and drying the substrate during operation 208. The residual etching solution is removed from the substrate surface during this operation by, for example, rinsing the surface with deionized water and drying with an inert gas, such as nitrogen or argon.

### Apparatus Examples

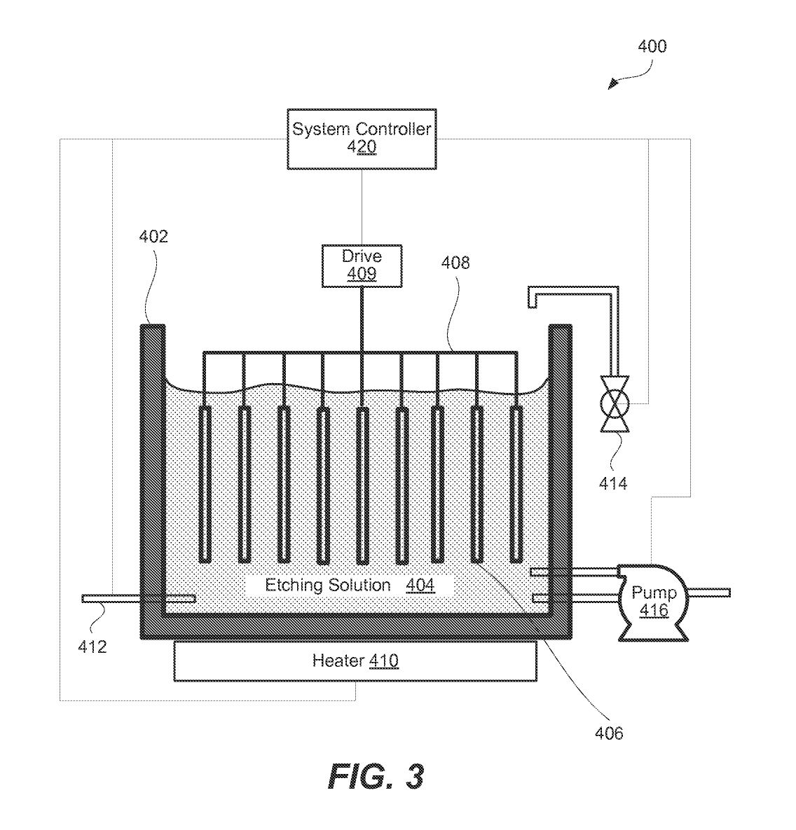

FIG. 3 illustrates a schematic representation of etching apparatus 400 for processing a semiconductor substrate to selectively remove silicon nitride from the surface of the substrate, in accordance with some embodiments. For clarity, some components of apparatus 400 are not included in this figure. Apparatus 400 includes bath 402 for containing etching solution 404. One or more semiconductor substrates 406 may be submerged into etching solution 404 for processing or, more specifically, for removal of silicon nitride structures. Substrate 406 may be supported by substrate holder 408, which may be attached to drive 409 for moving substrate holder 408. Specifically, substrate holder 408 may be moved to submerge substrates 406 into etching solution 404 for processing, remove substrates 406 from etching solution 404 after processing, and/or to move substrates 406 within etching solution 404 during processing (e.g., to agitate etching solution 404).

Apparatus 400 also includes heater 410 and temperature sensor 412 (e.g., a thermocouple) for maintaining etching solution 404 at a predetermined temperature. Heater 410 and temperature sensor 412 may be connected to system controller 420, which may control power supplied to heater 410 based on signals received from temperature sensor 412. Various features of system controller 420 are described below.

Apparatus 400 may also include a liquid delivery system 414 for supplying additional liquids and controlling the composition of etching solution 404. For example, some components of etching solution 404 may evaporate from bath 402, and these components may be replenished in bath 402 by liquid delivery system 414. Liquid delivery system 414 may be connected to and controlled by system controller 420. Various sensors (e.g., conductivity sensor, weight sensor) may be used to provide signals about potential changes in composition of etching solution 404. Apparatus 400 may be also equipped with pump 416 for recirculating etching solution 404 in bath 402 and other purposes. Pump 416 may be also connected to and controlled by system controller 420.

Apparatus 400 may include system controller 420 for controlling process conditions during silicon nitride etching processes. Controller 420 may include one or more memory devices and one or more processors with a central processing unit (CPU) or computer, analog and/or digital input/output connections, stepper motor controller boards, and the like. In some embodiments, controller 420 executes system control software including sets of instructions for controlling timing of operations, temperature of etching solution 404, composition of etching solution 404, and other parameters. Other computer programs and instruction stored on memory devices associated with controller may be employed in some embodiments.

### CONCLUSION

Although the foregoing concepts have been described in some detail for purposes of clarity of understanding, it will be apparent that some changes and modifications may be practiced within the scope of the appended claims. It should be noted that there are many alternative ways of implementing the processes, systems, and apparatuses. Accordingly, the present embodiments are to be considered as illustrative and not restrictive.

1. A method for processing semiconductor substrates, the method comprising:
providing a semiconductor substrate comprising a first structure and a second structure,
the first structure comprising a photoresist pattern, and
the second structure comprising silicon nitride;
exposing the semiconductor substrate to an etching solution,
the etching solution comprising hydrofluoric acid, a non-fluorinated acid, water, and one or more polar solvents selected from the group consisting of ethylene glycol (EG), propylene carbonate (PC), dichloromethane (DCM), tetrahydrofuran (THF), ethyl acetate, acetone, dimethylformamide (DMF), acetonitrile (MeCN), dimethyl sulfoxide (DMSO), propylene carbonate, formic acid, n-butanol, isopropanol (IPA), n-propanol, ethanol, and methanol,
wherein a volumetric ratio of water to hydrofluoric acid in the etching solution is between 1000:1 and 10,000:1; and
etching the second structure while the semiconductor substrate is exposed to the etching solution,
wherein an etching selectivity of the second structure to the first structure is greater than 5.

2. The method of claim 1, wherein the etching selectivity of the second structure to the first structure is greater than 50.

3. (canceled)

4. The method of claim 1, wherein an etching rate of the second structure is at least 3 Angstroms per minute.

5-7. (canceled)

8. The method of claim 1, wherein the etching solution is held at a temperature of between 60° C. and 90° C.

9. The method of claim 1, wherein the etching solution is held at a temperature of between 75° C. and 85° C.

10. The method of claim 1, wherein the volumetric ratio of water to hydrofluoric acid in the etching solution is at least about 5000:1.

11. The method of claim 1, wherein the second structure is removed from the semiconductor substrate.

12. The method of claim 11, wherein the second structure is between 20 Angstroms and 100 Angstroms thick prior to etching.

13. The method of claim 12, wherein a thickness of the first structure is reduced by less than 200 Angstroms while etching the second structure.

14. The method of claim 11, wherein the second structure is provided over a third structure, the third structure comprising silicon oxide, and wherein an etching selectivity of the second structure to the third structure is greater than 10.

15. The method of claim 1, wherein the second structure is formed by depositing silicon nitride using plasma enhanced chemical vapor deposition (PECVD).

16. The method of claim 1, wherein the second structure is formed by depositing silicon nitride using low pressure chemical vapor deposition (LPCVD).

17. The method of claim 1, wherein the second structure is disposed over a logic portion of the semiconductor substrate.

18. The method of claim 1, wherein the first structure is disposed over a memory portion of the semiconductor substrate.

19. A method for processing semiconductor substrates, the method comprising:
providing a semiconductor substrate comprising a first structure, a second structure, and a third structure,
the first structure comprising a photoresist pattern,
the second structure comprising silicon nitride and having a thickness of between 20 Angstroms and 1000 Angstroms, and
the third structure comprising silicon oxide and being covered by the second structure;
exposing the semiconductor substrate to an etching solution comprising hydrofluoric acid, a non-fluorinated acid, water, and one or more polar solvents selected from the group consisting of ethylene glycol (EG), propylene carbonate (PC), dichloromethane (DCM), tetrahydrofuran (THF), ethyl acetate, acetone, dimethylformamide (DMF), acetonitrile (MeCN), dimethyl sulfoxide (DMSO), propylene carbonate, formic acid, n-butanol, isopropanol (IPA), n-propanol, ethanol, and methanol,
wherein a volumetric ratio of water to hydrofluoric acid is between 1000:1 and 10,000:1, and
wherein the etching solution is kept at a temperature of between 60° C. and 90° C.; and
etching the second structure,
wherein the thickness of the first structure is reduced by less than 200 Angstroms.

20. The method of claim 19, wherein the second structure is disposed over a logic portion of the semiconductor substrate, and wherein the first structure is disposed over a memory portion of the semiconductor substrate.

21. The method of claim 1, wherein the non-fluorinated acid comprises one of hydrochloric acid, sulfuric acid, or nitric acid.

22. The method of claim 1, wherein the non-fluorinated acid comprises hydrochloric acid.

23. The method of claim 1, wherein the non-fluorinated acid comprises hydrochloric acid.

24. The method of claim 1, wherein the non-fluorinated acid comprises hydrochloric acid.
